(19) United States
(12) Patent Application Publication
(10) Pub. No.: US 2009/0065797 A1
(43) Pub. Date: Mar. 12, 2009

(54) Light emitting unit and liquid crystal display device using the same

(75) Inventors: Yong Suk Kim, Seoul (KR); Hoon Hur, Seongnam-si (KR)

Correspondence Address: MCKENNA LONG & ALDRIDGE LLP, 1900 K STREET, NW, WASHINGTON, DC, 20006, US

(73) Assignees: LG ELECTRONICS INC., Seoul (KR); LG Innotek Co., Ltd., Seoul (KR)

(21) Appl. No.: 12/230,447

(22) Filed: Aug. 28, 2008

(30) Foreign Application Priority Data
Aug. 29, 2007 (KR) 10-2007-0086943
Dec. 28, 2007 (KR) 10-2007-0140102

(51) Int. Cl. H01L 21/00; G02F 1/1335

(52) U.S. Cl. 257/99; 349/61; 257/E21.001

(57) ABSTRACT

A light emitting unit capable of widely adjusting brightness or size, and a liquid crystal display device using the same are disclosed. The light emitting unit includes a circuit board including circuit lines having a plurality of connecting members, and a plurality of unit module connected to the connecting members of the circuit board. The unit module is coupled with at least one light emitting device.

This application claims the benefit of Korean Patent Application No. 10-2007-0086943, filed on Aug. 29, 2007 and Korean Patent Application No. 10-2007-0140102, filed on Dec. 28, 2007 which are hereby incorporated by references as if fully set forth herein.

### BACKGROUND OF THE INVENTION

1. Field of the Invention

The present invention relates to a light emitting unit and a liquid crystal display device using the same, and more particularly, to a light emitting unit capable of widely adjusting a brightness or size, and a liquid crystal display device using the same.

2. Discussion of the Related Art

Light emitting diodes (LEDs) are well known as a semiconductor light emitting device which converts current to light. Since a red LED using GaAsP compound semiconductor was commercially available in 1962, it has been used, together with a GaP:N-based green LED, as a light source in electronic apparatuses including information communication appliances, for image display.

The wavelength of light emitted from such an LED depends on the semiconductor material used to fabricate the LED. This is because the wavelength of the emitted light depends on the band gap of the semiconductor material representing energy difference between valence-band electrons and conduction-band electrons.

Gallium nitride (GaN) compound semiconductor has been highlighted in the field of high-power electronic devices because it exhibits a high thermal stability and a wide band gap of 0.8 to 6.2 eV.

One of the reasons why GaN compound semiconductor has been highlighted is that it is possible to fabricate a semiconductor layer capable of emitting green, blue, or white light, using GaN in combination with other elements, for example, indium (In), aluminum (Al), etc.

Thus, it is possible to adjust the wavelength of light to be emitted, using GaN in combination with other appropriate elements. Accordingly, where GaN is used, it is possible to appropriately determine the materials of a desired LED in accordance with the characteristics of the apparatus to which the LED is applied. For example, it is possible to fabricate a blue LED useful for optical recording or a white LED to replace a glow lamp.

Since emission of white light is possible, the white light can be used for an illumination purpose. For example, white light can be used for a backlight unit of a liquid crystal display (LCD) device.

The LCD device, which is a light reception type flat display, has no ability to emit light by itself. For this reason, the LCD device forms an image by selectively transmitting illumination light irradiated from the external of the LCD device. To this end, a light source must be arranged at the back side of the LCD device, in order to illuminate the LCD device. This light source is called a “backlight unit (BLU)”

For a backlight unit used in an LCD device, a plurality of white LEDs may be arranged on a substrate such that light emitted from the white LEDs can be uniformly diffused.

FIG. 1 illustrates front circuit boards of a conventional LED backlight unit. As shown in FIG. 1, a plurality of circuit boards 1 is mounted to a front surface of the backlight unit. In the case of FIG. 1, 6 circuit boards 1 are used. Each circuit board 1 includes a plurality of mounts 2, to which LEDs are mounted, respectively, and connectors 3 arranged at one end of the circuit board 1, and electrically connected to the mounts 2.

In the above-mentioned conventional LED backlight unit, it is difficult to freely vary the size of the backlight unit. This is because the circuit boards 1, which are adapted to drive LEDs mounted thereon, are arrayed to meet a fixed size of the backlight unit.

Where the total size of the circuit boards 1 is enlarged to meet the recent tendency of the backlight unit toward an enlarged size, there may be problems of an increase in the failure rate of the circuit boards 1 and an increase in equipment investment costs.

Furthermore, the existing LED modules cannot be applied to backlight units having various sizes. For this reason, when it is desired to develop a backlight unit having a new size, LED modules applicable to the new-size backlight unit should also be newly developed.

Thus, the conventional LED backlight unit has a limitation in varying the size thereof in accordance with the size of the LCD panel, for which the LED backlight unit is used.

### SUMMARY OF THE INVENTION

Accordingly, the present invention is directed to a light emitting unit and a liquid crystal display device using the same that substantially obviate one or more problems due to limitations and disadvantages of the related art.

An object of the present invention is to provide a light emitting unit, which can provide a modular light emitting unit capable of achieving the manufacture of a light emitting unit having an optional luminance or size, and a liquid crystal display device using the light emitting unit.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a light emitting unit comprises: a circuit board comprising circuit lines having a plurality of connecting members; and a plurality of unit modules connected to the connecting members of the circuit board, the unit modules being coupled with at least one light emitting device.

In another aspect of the present invention, a light emitting unit comprises: a plurality of first circuit boards including at least one light emitting device electrically connected to a first circuit pattern having a first terminal pattern; and a second circuit board including a second circuit pattern having a plurality of second terminal patterns connected to the first terminal patterns of the first circuit boards.

In another aspect of the present invention, a liquid crystal display device comprises: a backlight unit comprising a circuit board including circuit lines having a plurality of connecting members, and a plurality of unit module connected to the connecting members of the circuit board, the unit modules being coupled with at least one light emitting device; and a liquid crystal panel arranged on the backlight unit.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a plan view illustrating a circuit board of a general light emitting unit;

FIG. 2 is a schematic view illustrating an example of a light emitting unit according to the present invention;

FIGS. 3 to 5 are schematic views illustrating a first embodiment of the present invention, in which

FIG. 3 is a schematic view illustrating a unit module,

FIG. 4 is a plan view illustrating a circuit board, and

FIG. 5 is an exploded sectional view illustrating the unit module and the circuit board;

FIGS. 6 to 9 are schematic views illustrating a second embodiment of the present invention, in which

FIG. 6 is a schematic view illustrating a unit module,

FIG. 7 is a plan view illustrating the coupling between the unit module and a circuit board, and

FIG. 8 is a cross-sectional view taken along the line A-A of FIG. 7, illustrating an example of the coupling between the unit module and the circuit board,

FIG. 9 is a cross-sectional view taken along the line A-A of FIG. 7, illustrating another example of the coupling between the unit module and the circuit board,

FIG. 10 is a plan view illustrating a third embodiment of the present invention;

FIG. 11 is a plan view illustrating a fourth embodiment of the present invention;

FIG. 12 is a plan view illustrating a first board;

FIG. 13 is a view illustrating terminal patterns of first and second boards;

FIG. 14 is a view illustrating a coupled state of the first and second boards;

FIG. 15 is a view illustrating dummy patterns included in the terminal patterns;

FIGS. 16 and 17 are views illustrating another shape of coupling portions;

FIG. 18 is a view illustrating the formation of terminal patterns extending to edge surfaces of the boards;

FIG. 19 is a view illustrating a fifth embodiment of the present invention;

FIG. 20 is a view illustrating a coupled state of the first and second boards;

FIG. 21 is a view illustrating a sixth embodiment of the present invention;

FIG. 22 is a view illustrating a coupled state of the first and second boards;

FIG. 23 is an exploded perspective view illustrating an example of a liquid crystal display device;

FIG. 24 is a sectional view illustrating an example of a liquid crystal panel;

FIG. 25 is a block diagram illustrating a liquid crystal TV including a liquid crystal display device; and

FIG. 26 is a block diagram illustrating a liquid crystal monitor including a liquid crystal display device.

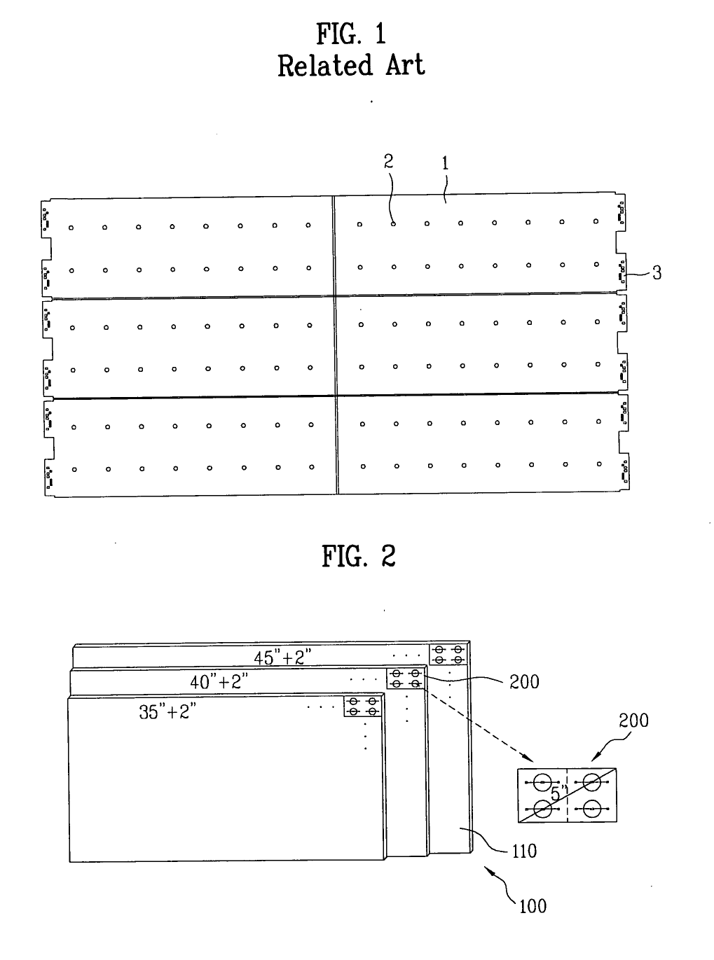

### DETAILED DESCRIPTION OF THE INVENTION

Reference will now be made in detail to the preferred embodiments of the present invention, examples of which are illustrated in the accompanying drawings.

The present invention may, however, be embodied in many alternate forms and should not be construed as limited to the embodiments set forth herein. Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims.

Like numbers refer to like elements throughout the description of the figures. In the drawings, the thickness of layers and regions are exaggerated for clarity.

It will be understood that when an element such as a layer, region or substrate is referred to as being “on” another element, it can be directly on the other element or intervening elements may also be present. It will also be understood that if part of an element, such as a surface, is referred to as “inner,” it is farther to the outside of the device than other parts of the element.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms.

These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

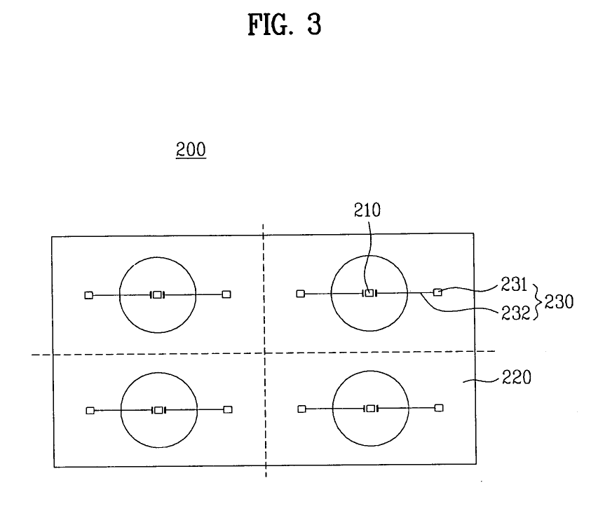

As shown in FIG. 2, unit light emitting device modules 200 each having a certain size are provided. These modules 200 are arrayed to manufacture a light emitting unit 100, which may be used as a backlight unit for an LCD device.

Thus, it is possible to manufacture a light emitting unit having any usable size by arraying a desired number of unit light emitting device modules 200, without using a method in which the size of a light emitting unit such as the existing backlight unit is divided into a sub-size, and circuit boards, for example, printed circuit boards (PCBs), which have the sub-size, are arrayed.

Where each unit module 200 has a size (diagonal length) of, for example, 5 inches (5″), it is possible to manufacture a light emitting unit 100 having an optional brightness or size by arraying the 5″ unit modules 200 in a number corresponding to the size of a light emitting unit, which may have a size of 37″, 42″, 47″, 52″, or 57″, to provide a desired brightness.

Although there is an area, which is not occupied by the unit modules 200 (about 2″ in this case), it is possible to sufficiently control the brightness of the light emitting unit 100 by appropriately modifying the design of a wall functioning as an outside reflector of the light emitting unit 100.

In each unit module 200, only the electrodes of light emitting devices are present. A practical circuit array is controlled by a circuit board 110 constituted by an array of unit modules each constituted by light emitting devices coupled to a module circuit board.

The circuit board 110 includes a plurality of circuit lines arranged on the light emitting unit 100, and connectors provided at the circuit lines. Drivers, which drive the light emitting devices, may be connected to the circuit lines.

The circuits of the unit modules 200 are connected to the connectors of the circuit board 110, respectively. In the light emitting unit 100 having the above-described array, the light emitting devices may be driven for respective unit modules 200. If necessary, the light emitting devices in each unit module 200 may be freely individually driven. Thus, it is possible to effectively control the power consumption and contrast of the light emitting unit 100.

The light emitting unit 100, which has a modular structure, may be more efficient in terms of maintenance and repair. In the case of a conventional light emitting unit, the failure of a part of light emitting devices requires the replacement of the entire circuit board. For this reason, vast expense for maintenance and repair is required. This phenomenon becomes more severe in a light emitting unit having a larger size.

In the case of the light emitting unit 100 according to the present invention, however, it is possible to replace only the failed unit module 200. Accordingly, the light emitting unit 100 of the present invention is more efficient in terms of maintenance and repair.

Thus, the present invention can be applied to a light emitting unit having any size by preparing unit modules 200 having a minimum size, and coupling the unit modules 200 in a number corresponding to a light quantity required for the applied light emitting unit in accordance with the size of the light emitting unit.

When this method is accomplished, it is unnecessary to separately manufacture and manage light emitting device modules in accordance with various sizes of light emitting units. In accordance with the present invention, unit modules 200 having a constant size are manufactured so that they can be applied to a light emitting unit having any size. Additionally, it is possible to efficiently achieve equipment investment and stock management, since the size of the unit modules 200 is small, it is also possible to achieve an enhancement in productivity and a reduction in failure rate.

### FIRST EMBODIMENT

FIG. 3 illustrates an example of a unit module. Referring to FIG. 3, a unit light emitting device module 200 includes a modular circuit board 220, and four light emitting devices 210 arrayed on the modular circuit board 220. As shown in FIG. 3, the four light emitting devices 210 are arrayed on the modular circuit board 220 in 2 rows and 2 columns.

If necessary, the number of the light emitting devices 210 arrayed on one modular circuit board 220 may be varied. For example, only one light emitting device 210 may be arranged on one unit modular circuit board 220. Two or three light emitting devices 210 may be arrayed on one unit modular circuit board 220. Also, four or more light emitting devices 220 may be arrayed on one unit modular circuit board 220.

Each modular circuit board 220 includes a circuit 230, which includes contacts 231 connected to the light emitting devices 210 of the modular circuit board 220. The connection between the corresponding contact 231 and light emitting device 210 is achieved by a wire 232.

A pair of contact 231 is arranged at opposite sides of each light emitting device 231 such that they function as an anode and a cathode, respectively. The light emitting devices 210 in each modular circuit board 220 are connected by the circuit 230 of the modular circuit board 220.

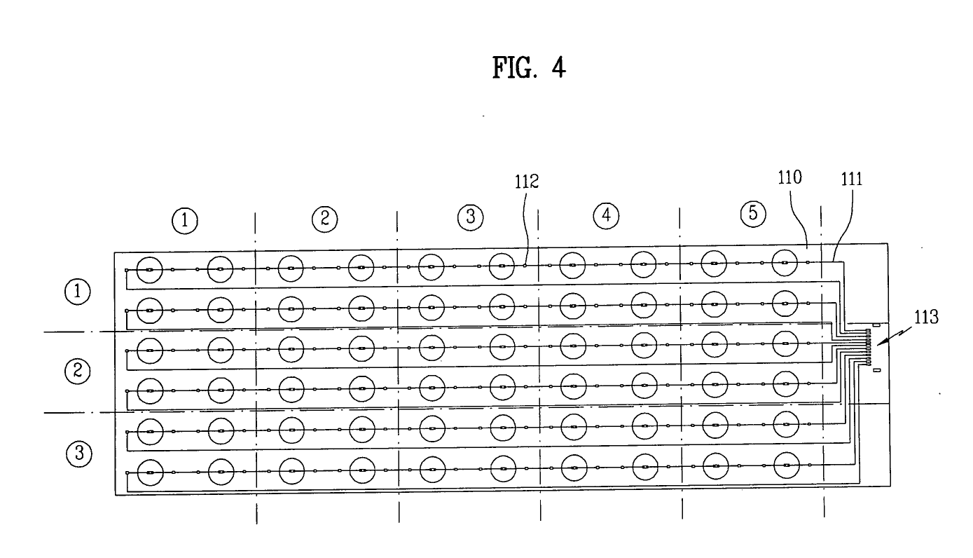

As shown in FIG. 4, a plurality of unit modules 200 are arrayed on the circuit board 110, to provide a desired brightness and size. In this case, the unit modules 200 are connected to a driver (not shown) via circuit lines 111 arranged on the circuit board 110.

The circuit lines 111 of the circuit board 110 are formed to couple a desired number of unit modules 200 on the light emitting unit. FIG. 4 illustrates an example in which circuit lines 111 are arranged to couple unit modules 200 arrayed in 5 columns and 3 rows.

Each circuit line 111 includes contacts 112, which are placed at respective positions of the contacts 231 of unit modules 200 when the unit modules 200 are coupled by the circuit line 111. The light emitting devices 210 of the unit modules 200 are connected to the circuit line via the contacts 112.

The plurality of circuit lines 111 may be converged at one side of the circuit board 110, to form a connecting line 113. The connecting line 113 may be connected to the driver via a separate connector line connected to the connecting line 113.

Alternatively, the circuit lines 111 may be converged on the single circuit board 110 in several directions. For example, the circuit lines 111 are divided into two groups, namely, even lines and odd lines, such that the even lines and odd lines are converged, to form connecting lines 113 at two positions, respectively. The circuit lines 111 may also be converged in multiple directions, to form connecting lines 113 at several positions, respectively. In particular, where the circuit board 110 has a large size, it may be advantageous to form connecting lines 113 at several positions, as described above.

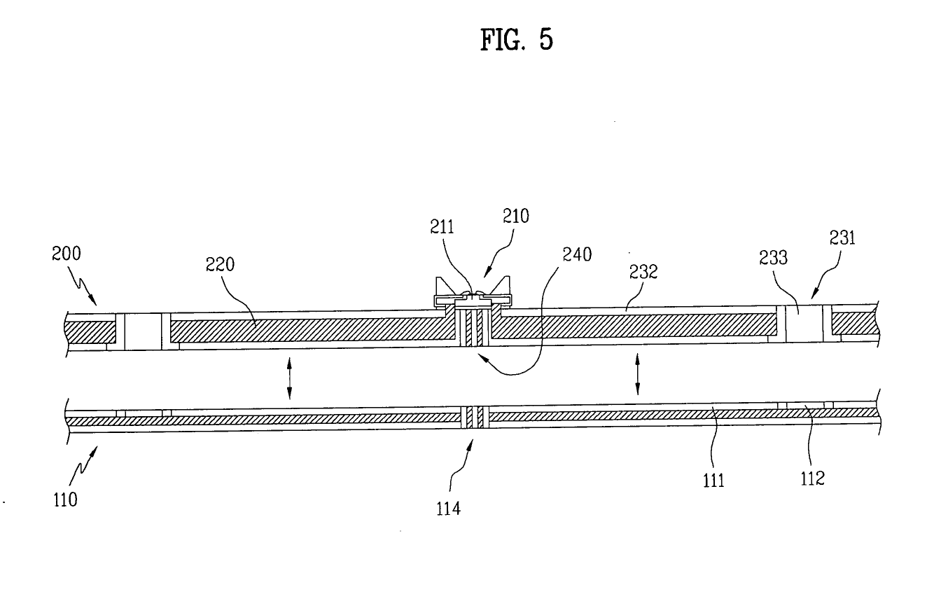

Meanwhile, as shown in FIG. 5, a heat discharge member 240 may be formed at the modular circuit board 220 of each unit module 200, to discharge heat generated from the light emitting devices 210 coupled to the unit module 200.

Also, a heat transfer member 114 may be formed at the circuit board 110, to which the unit module 200 is coupled. The heat transfer member 114 is connected to the heat discharge member 240, to transfer heat via air.

The heat discharge member 240 may comprise at least one through holes formed through the modular circuit board 220. A metal may be coated on an inner surface of the through hole, or filled in the through hole. In detail, a heat sink 211 is provided at each light emitting device 210. In this case, the heat sink 211 can externally discharge heat via the heat discharge member 240, which is constituted by a through hole coated or filled with a metal.

Thus, heat transferred via the heat discharge member 240 can be externally discharged via the heat transfer member 114 formed at the circuit board 110 to be connected to the heat discharge member 240. A separate heat discharger, which is installed at the light emitting unit, may be connected to the heat transfer member 114.

In the case of a general circuit board, it is made of an insulator such as flame retardant-4 (FR4). Where the circuit board 220 is made of such FR4, heat generated at the bottom of each light emitting device 210 can flow up to the wires 232. In this, however, the heat may be difficult to be transferred to the FR4 insulator circuit board 220. To this end, the above-described heat discharge member 240 is formed, in order to effectively discharge heat generated from the light emitting devices 210.

Meanwhile, the contacts 231 of each unit module 200 and the corresponding contacts 112 of the circuit board 110 may be formed to have shapes enabling the contacts 231 and 112 to be simultaneously coupled while coming into contact with each other. For example, it is desirable for each contact 112 to have a structure capable of enclosing the corresponding contact 231 of the unit module 200, in order to enable the unit module 200 to be coupled to the circuit board 110 without using a separate fastener.

A via hole 233 may be formed through each contact 231 of the unit module 200, to effectively guide a flow of heat.

In the case of the light emitting unit having the above-described modular structure, it is possible to freely individually drive the light emitting devices 210 of each unit module 200.

That is, one of the main advantages of the modular light emitting unit is in that the driving of the light emitting unit can be carried out in a divisional manner. That is, the light emitting devices 210 in one light emitting unit can be freely divided into a desired number of groups each including a desired number of light emitting units so that the driving of the light emitting unit can be carried out for each light emitting unit group. Accordingly, it is possible to individually control the driving of the light emitting units, and thus, to achieve point dimming.

Meanwhile, the light emitting unit, which has a modular structure as described above, may include unit modules 200 set as basic modules each including three, four, or five modules. Accordingly, the shape of the circuit board 110 can be appropriately changed or designed to meet the number of unit modules 200.

The shape of the circuit board 110 can be changed in accordance with the shape and coupling method of the unit module 200. Accordingly, it is possible to reduce the number of modules totally used, and to reduce the number of assembling processes used in an assembling procedure, and thus, to achieve a reduction in process costs, as compared to the case in which a single module is used.

For example, where a backlight unit having a size of 47″, 81 modules are used in accordance with a general module assembly scheme. However, where unit modules 200 set as basic modules each including three, four, or five modules are used, it is possible to reduce the number of the used unit modules 200.

For example, where basic modules each including three modules are used, it is possible to constitute a 47″ size by assembling only 27 unit modules 200. Where both basic modules each including four modules and basic modules each including five modules are used, it is possible to constitute a 47″ size by assembly only 18 unit modules 200.

Where three, four, or five modules are used for one basic module, it is possible to easily meet various sizes, as compared to the case using single-modules. The following Table 1 describes module assembly examples and numbers of modules used for various sizes.

TABLE 1

| | Number of Required | |
|---|---|---|
| | Modules (Conventional | |
| Size | Case Using Single- | Number of Required Modules |
| (inch) | Modules) | (Present Invention) |
| 37 | 49 | 3-Module: 7, and 4-Module: 7 |
| | | Total: 14 Modules |
| | | \textcircled{1} 3-Module: 8, and 5- |
| | | Module: 8 |
| | | Total: 16 Modules |
| 42 | 64 | \textcircled{2} 4-Module: 16 |
| | | \textcircled{1} 3-Module: 27 |
| | | \textcircled{2} 4-Module: 9, and 5- |
| | | Module: 9 |
| 47 | 81 | Total: 18 Modules |
| | | \textcircled{1} 3-Module: 20, and 4- |
| | | Module: 10 |
| | | Total: 30 Modules |
| 52 | 100 | \textcircled{2} 5-Module: 20 |

### SECOND EMBODIMENT

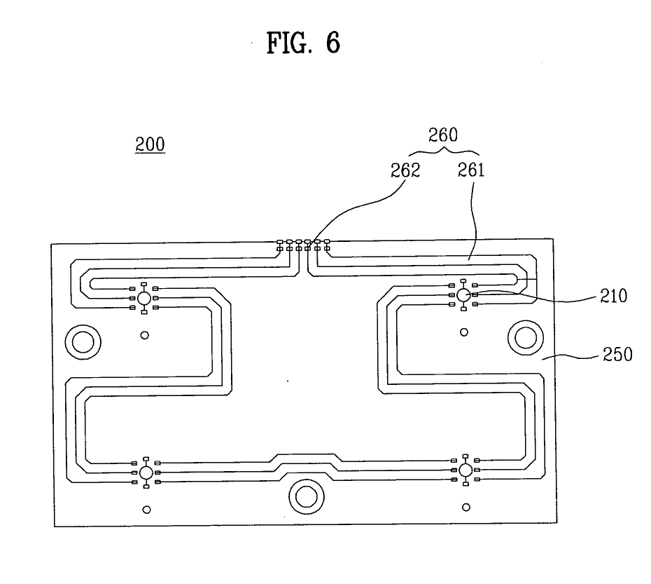

FIG. 6 illustrates another example of the unit module. In this case, four light emitting devices 210 are arrayed on a modular circuit board 250. The modular circuit board 250 includes a circuit 260, which includes conductive lines 261 each connected to the light emitting devices 210, and outer connectors 262 respectively connected to the conductive lines 261.

As shown in FIG. 6, the four light emitting devices 210 are arrayed on the modular circuit board 250 in 2 rows and 2 columns.

Since the light emitting devices 210 are electrically connected by the conductive lines 261, as described above, the modular circuit board 250 itself can drive the four light emitting devices 210.

Since the conductive lines 261 are connected to the outer connectors 262, as described above, the light emitting devices 210 is coupled to a circuit board 120, so that it can receive electric power from the circuit board 120 via the outer connectors 262.

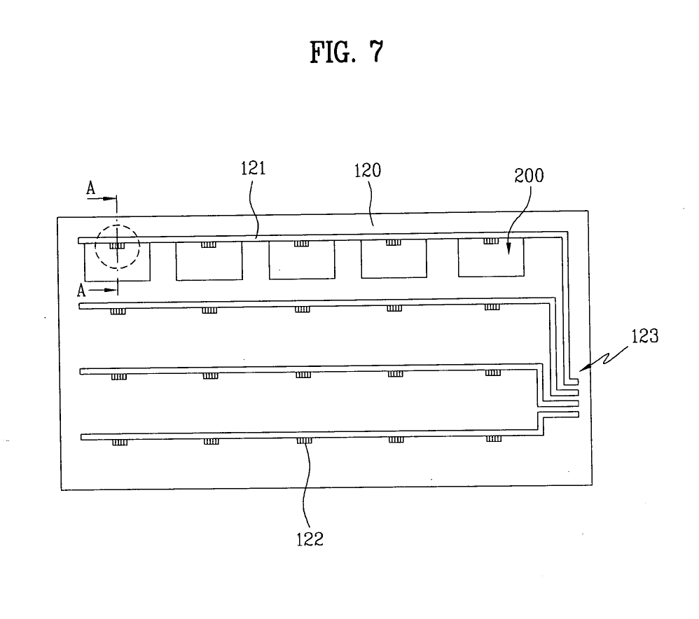

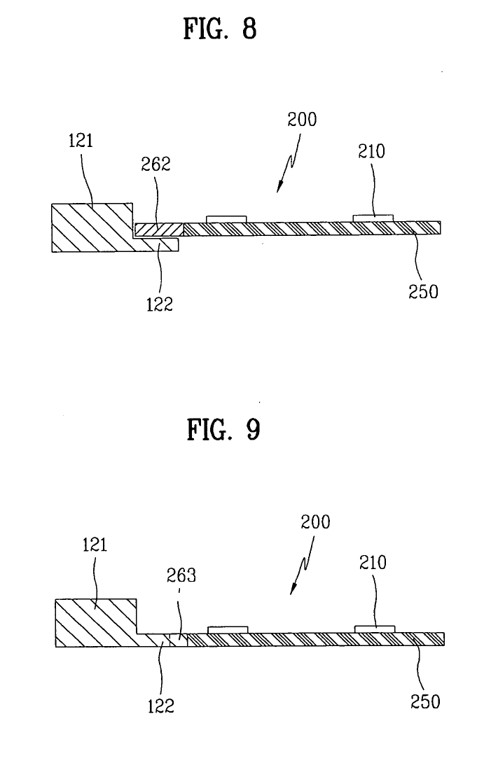

As shown in FIG. 7, a plurality of unit modules 200 each having the above-described configuration are arrayed on the circuit board 120, to provide a desired brightness and size. In this case, the unit modules 200 are connected to a driver (not shown) via circuit lines 121 arranged on the circuit board 120.

Couplers 122 are arranged at intervals of spacing on each circuit line 121, as connectors to couple the unit modules 200 according to the embodiment of FIG. 6 to the circuit board 120. The connectors 262 of each unit module 200 are coupled to the corresponding couplers 122, so that the unit module 200 can be coupled to the circuit board 120.

Thus, each unit module 200 may be arranged on a plane flush with a plane defined by the circuit board 120, namely, a main plane of the light emitting unit. That is, although the unit modules 200 in the above-described first embodiment are arrayed on the circuit board 110 (FIG. 5), the unit modules in this embodiment may be arranged on the same plane as the circuit board 120. Accordingly, it is possible to more thinly manufacture the light emitting unit.

The plurality of circuit lines 121 may be converged at one side of the circuit board 120, to form a connecting line 123. The connecting line 123 may be connected to the driver via a separate connector line connected to the connecting line 123.

The coupling between the couplers 122, which are provided at each circuit line 121, and the corresponding unit module 200 may be achieved in such a manner that the connectors 262 of the unit module 200 are in contact with the couplers 122 of the circuit line 121 in a vertical direction, respectively, as shown in FIG. 8.

Alternatively, the connectors 262 and couplers 122 may be coupled in the form of male and female coupling shapes.

The unit modules 200 may be driven in a divisional manner for each unit module 200. That is, one modular circuit board 250 is a smallest unit of divisional driving. The unit of divisional driving may be determined in accordance with the number of the arranged modular circuit boards 250.

### THIRD EMBODIMENT

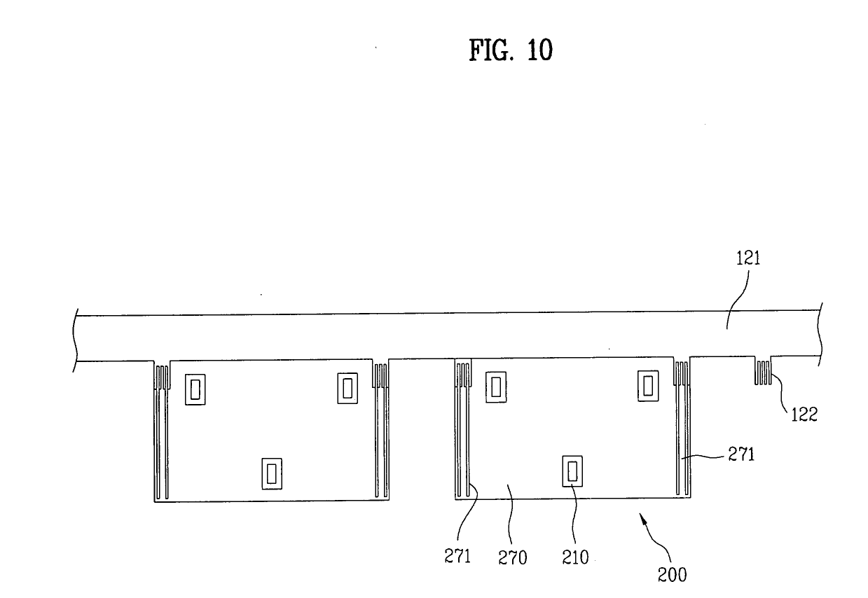

FIG. 10 illustrates an embodiment in which three light emitting devices 210 are coupled to one unit module 200, and the light emitting devices 210 are connected with connectors 271 at opposite sides of a modular circuit board 270.

The modular circuit board 270 includes a circuit, which includes conductive lines connected to the light emitting devices 210 of the modular circuit board 270. The conductive lines are connected to the connectors 271 of the modular circuit board 270.

As shown in FIG. 10, the connectors 271 may be coupled to couplers 122 arranged on the corresponding circuit line 121, respectively. Two couplers 122 are arranged on each circuit line 121 for each unit module 200.

Similarly to the second embodiment, the unit modules 200 in this embodiment may be driven in a divisional manner for each unit module 200. That is, one modular circuit board 270 is a smallest unit of divisional driving. The unit of divisional driving may be determined in accordance with the number of the arranged modular circuit boards 270.

### FOURTH EMBODIMENT

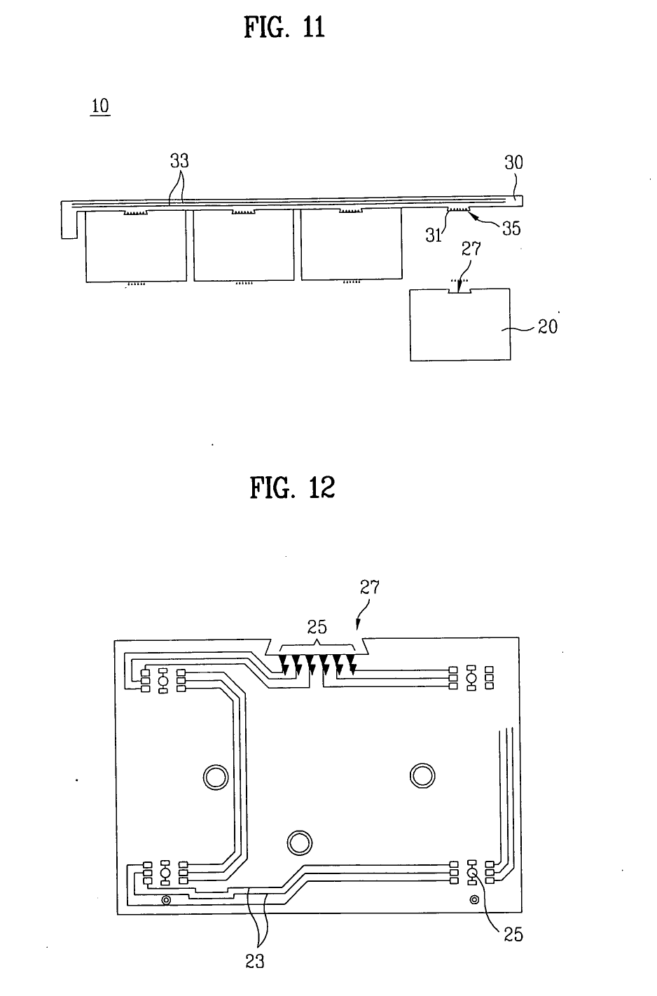

Referring to FIGS. 11 and 12, a light emitting unit 10 according to a fourth embodiment is illustrated. The light emitting unit 10 includes first boards 20 each including light emitting devices 21, and a second board 30, to which the first boards 20 are coupled. The second board 30 may be identical to the circuit boards of the previous embodiments. The first boards 20 may be identical to the modular circuit boards of the previous embodiments.

Each first board 20 has a certain size, for example, a 4″ size. Of course, the size of each first board 20 may be varied into, for example, 5″ or 3″, if necessary.

Each first board 20 has a rectangular shape with regard to a planar shape. The light emitting devices 21 of each first board 20 are arranged at respective corners of the first board 20. Thus, the light emitting devices 21 are arranged on the first board 20 in a 2×2 array. The number of light emitting devices 21 may be appropriately adjusted in accordance with a required intensity of light. For example, six light emitting devices 21 may be arranged on the first board 20 in a 2×3 array, to obtain an increased intensity of light. In order to obtain a reduced intensity of light, two light emitting devices 21 may be arranged on the first board 20 in a 1×2 array.

The light emitting devices 21 of each first board 20 are electrically connected by circuit patterns 23 printed on the first board 20.

Where three light emitting diodes, which emit monochromatic light of different colors (for example, red, green, and blue), are packaged to constitute each light emitting device 21 emitting white light, three linear circuit patterns 23 are printed among the light emitting devices 21. All light emitting devices 21 in each first board 20 are electrically connected by the circuit patterns 23.

The circuit patterns 23 are connected to a first terminal pattern 25 formed at an edge of the first board 20. The first board 20 receives a drive signal from the second board 20 via the first terminal pattern 25, and sends the received drive signal to the light emitting devices 21. In response to the drive signal, each light emitting device 21 is turned on or off.

A first coupler 27 is formed at each first board 20. The first coupler 27 mechanically connects the first board 20 to the second board 30. In the drawings, the first coupler 27 is illustrated as a recess formed at an edge of the first board 20. In this case, the first terminal pattern 25 may be positioned at a central portion of the recess. Hereinafter, the first coupler 27 will be referred to as a “recess”.

The recess 27 not only determines a position, at which the first board 20 will be coupled to the second board 30, but also increases the coupling force between the first and second boards 20 and 30.

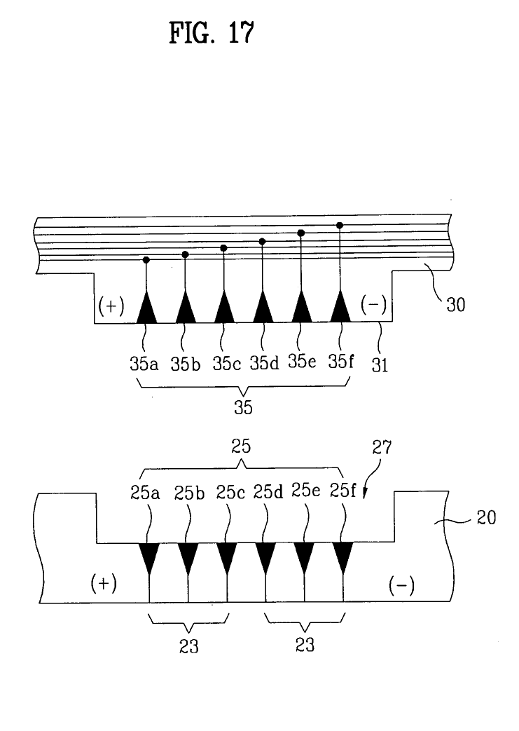

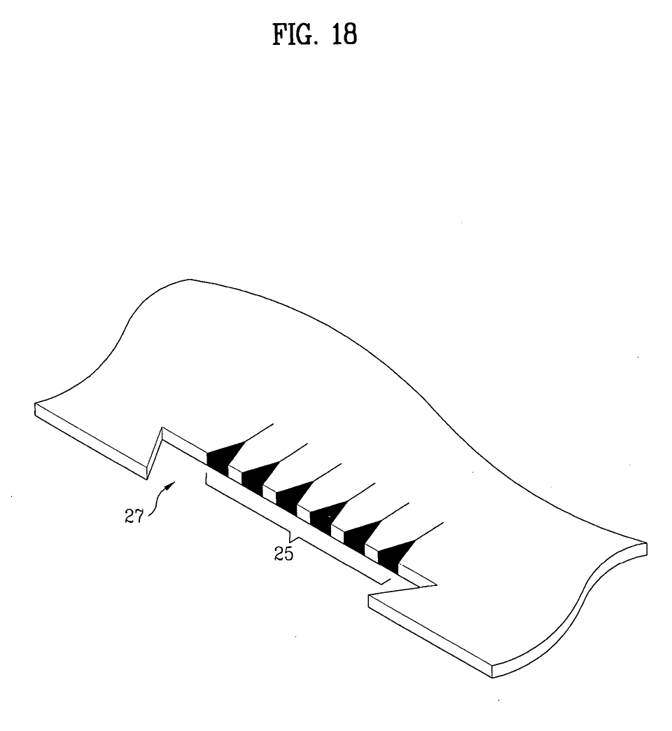

Although the recess 27 is illustrated in the drawings as having a trapezoidal shape with regard to a planar shape, it is not limited to such a shape. The recess 27 may have various shapes, for example, a rectangular shape having protrusions or a hemi-spherical shape (FIGS. 16 and 17).

The second board 30 has a horizontally-elongated bar shape, in order to enable a plurality of first boards 20 to be coupled to the second board 30. The second board 30 includes a plurality of second couplers 31, which will be coupled with the recesses 27 of the first boards 20, respectively. Each second coupler 31 is coupled with the corresponding first coupler 27 in the form of male and female coupling shapes. Accordingly, each second coupler 31 may have a protrusion shape engagable with the corresponding recess 27. The protrusion extends from the second board 30 in one direction. Hereinafter, each second coupler 31 will be referred to as a “protrusion”.

Each protrusion 31 is provided with a second terminal pattern 35 engagable with the first terminal pattern 25 positioned at the corresponding recess 27. The second terminal pattern 35 is connected to circuit patterns 33. The circuit patterns 33 are linearly printed in a longitudinal direction of the second board 30. The circuit patterns 33 are electrically connected with a plurality of second terminal patterns 35 formed on the second board 30.

Meanwhile, a driver (not shown), which functions to turn on or off the light emitting devices 21 arranged on each first board 20, is connected to one end of each circuit pattern 33. Accordingly, a drive signal applied via the driver is sent to the second terminal patterns 35 via the circuit patterns 33 of the second board 30, and is then sent to the light emitting devices 21 of the first boards 20 via the first terminal patterns 25 engaged with the second terminal patterns 35.

As described above, each first board 20 is provided with a plurality of light emitting devices 21, which are electrically connected by the circuit patterns 23 of the first board 20. The second board 30, to which a plurality of first board 20 are coupled, is provided with second terminal patterns 35, in order to supply a drive signal to the first boards 20.

Thus, in accordance with the fourth embodiment, illumination can be achieved using the first boards 20, each of which is configured in the form of a unit module. Accordingly, it is possible to obtain a desired brightness and size by appropriately adjusting the number of the first boards 20. Since the first and second boards 20 and 30 are coupled under the condition in which they are flush with each other, it is possible to reduce the thickness of the light emitting unit 10 as much as possible. Of course, the second board 30 may be provided in the form of a plurality of rows.

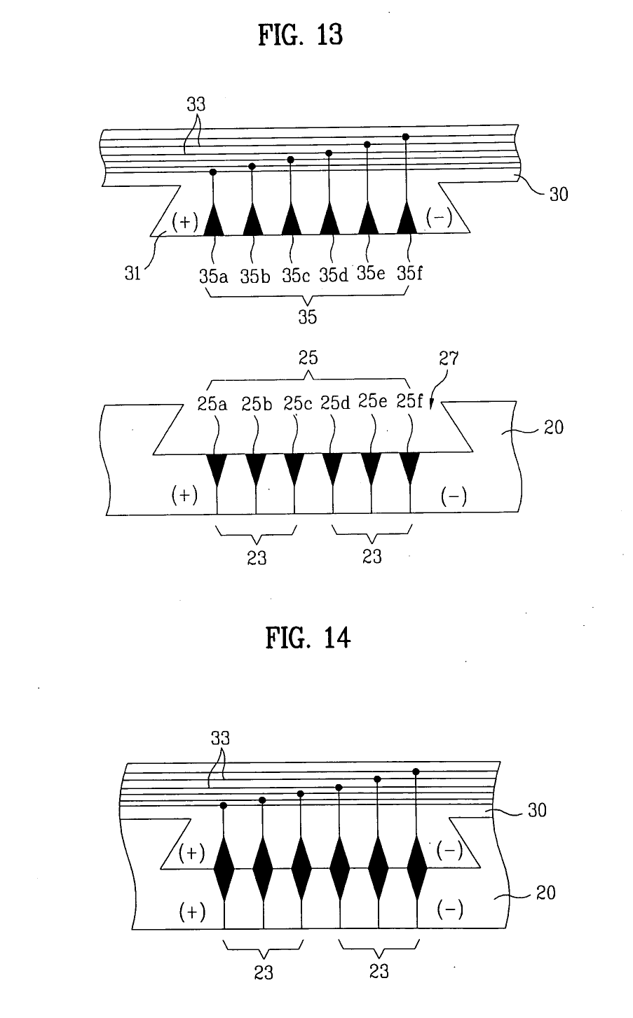

Hereinafter, the terminal patterns of the first and second boards will be described in detail with reference to FIGS. 13 and 14. FIG. 13 is a view illustrating the terminal patterns of the first and second boards. FIG. 14 is a view illustrating a coupled state of the first and second boards.

Referring to FIGS. 13 and 14, the first board 20 is provided with a recess 27 formed at an edge of the first board 20. The first terminal pattern 25 is formed in the recess 27. As described above, the first terminal pattern 25 is connected to the circuit patterns 23 connected to the light emitting devices 21 of the first board 20.

The first terminal pattern 25 includes a plurality of signal lines 25a to 25f, which are connected to the circuit patterns 23, respectively.

Where each light emitting device 21 comprises 3-color light emitting diodes, as described above, it is necessary to use three inputs and three outputs, in order to turn on/off the light emitting diodes. In this case, accordingly, the first terminal pattern 25 should include at least six signal lines, namely, at least the signal lines 25a to 25f. A certain voltage may be input to three signal lines, for example, the signal lines 25a to 25c. The remaining three signal lines, for example, the signal lines 25d to 25f, may be grounded.

The signal lines 25a to 25f have a triangular shape having a width increasing gradually as it extends from the circuit patterns 23 toward the recess 27.

Similarly, the second terminal pattern 35 includes a plurality of signal lines 35a to 35f. The signal lines 35a to 35f have a triangular shape having a width increasing gradually as it extends from the circuit patterns 33 toward the protrusion 31.

Accordingly, when the recess 27 of the first board 20 is fitted around the protrusion 31 of the second board 30, the signal lines 25a to 25f of the first board 10 are engaged with the signal lines 35a to 35f of the second board 30, so that they form a diamond shape (FIG. 14).

Under this condition, the first and second terminal patterns 25 and 35 are soldered, to connect the circuit patterns of the first and second boards 20 and 30. Since the signal lines 25a to 25f and signal lines 35a to 35f have an increased width in a joining region where the first and second boards 20 and 30 are in contact with each other, the solder is spread around the joining region, and solidified, without penetrating into a gap defined between the first and second boards 20 and 30 in the joining region. As a result, the solder is smoothly attached to the joining region without being caved in toward the gap. Thus, a coupling force provided by the soldering can be enhanced.

Thus, in accordance with the fourth embodiment of the present invention, the first and second boards 20 and 30 are primarily coupled, using the recess 27 and protrusion 31 respectively formed at the first and second boards 20 and 30, and is secondarily coupled, using the soldering of the first and second terminal patterns 25 and 35. Accordingly, the first and second boards 20 and 30 are firmly coupled because the coupling force provided by the soldering is added to the mechanical coupling force.

Where the soldering is used, as in this embodiment, it is also possible to achieve the electrical connection between the first and second boards 20 and 30.

In order to more reliably achieve the electrical connection between the first and second terminal patterns 25 and 35, the signal lines 25a to 25f and signal lines 35a to 35f may be further extended to the edge surfaces of the substrates 20 and 30, respectively. In this case, when the protrusion 31 of the second board 30 is fitted in the recess 27 of the first board 20, the terminal patterns 25 and 35 come into contact with each other, so that they are electrically connected.

In this embodiment, all signal lines 25a to 25f constituting the terminal pattern 25 and all signal lines 35a to 35f constituting the terminal pattern 35 have been described as being connected to the circuit patterns 23 and 33, respectively.

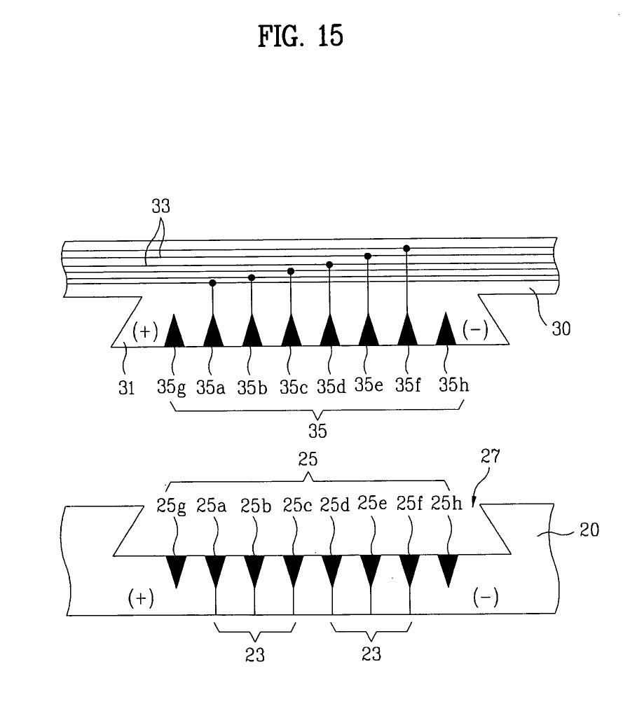

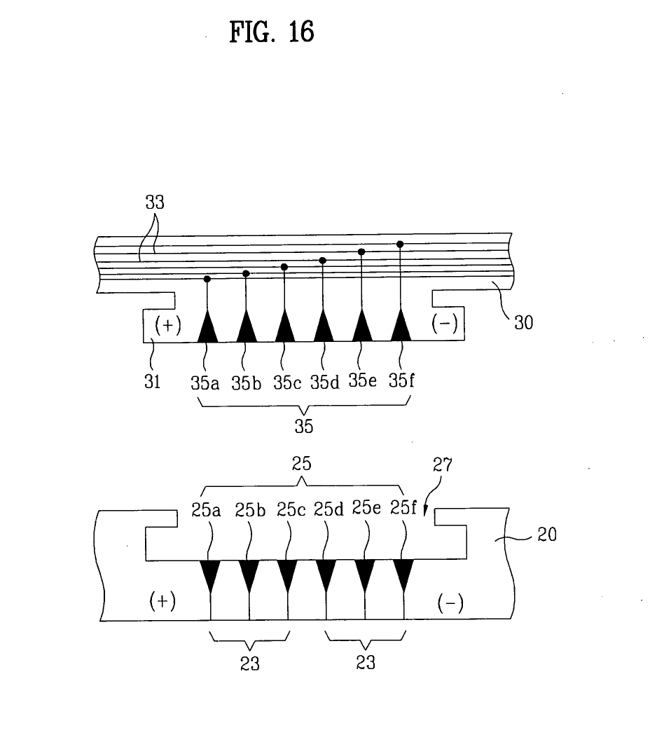

However, the terminal patterns 25 and 35 may be configured to further include dummy patterns 25g and 25h and dummy patterns 35g and 35h, respectively, as shown in FIG. 15. Although the dummy patterns 25g and 25h and dummy patterns 35g and 35h are not electrically connected, they are used to increase the coupling force between the first and second boards 20 and 30.

To this end, the first terminal pattern 25 includes, in addition to the signal lines 25a to 25f connected to the circuit patterns 23, dummy patterns 25g and 25h not connected to the circuit patterns 23. The dummy patterns 25g and 25h may be formed at opposite sides of the signal lines 25a to 25f, respectively. The dummy patterns 25g and 25h are soldered, simultaneously with the soldering of the signal lines 25a to 25f.

In this embodiment, each light emitting device 21 has been described as comprising a light emitting device constituted by packaging three light emitting diodes emitting monochrome light of different colors, to emit white light. However, the present invention is not limited to such a light emitting device. For example, each light emitting device 21 may comprise a light emitting diode emitting monochrome light. In this case, only two signal lines are needed. In this case, accordingly, the remaining signal lines may be used as dummy patterns.

In accordance with the above-described embodiment, the light emitting unit 10 is manufactured as a plurality of first boards 20, which have a modular structure, are coupled. Accordingly, the brightness or size of the light emitting unit 10 can be freely adjusted in accordance with the size of a display, to which the light emitting unit 10 is applied.

Where the light emitting unit 10 is failed, it is possible to selectively repair only the failed module (namely, the failed first board 20) without repairing the entire portion of the light emitting unit 10.

The terminal patterns 25 and 35 have a maximum width in a region where the boards 20 and 30 are engaged with each other. Accordingly, the solder can be solidified without being caved in the region where the boards 20 and 30 are engaged with each other. Thus, the coupling force of the solder can be enhanced.

Also, the first and second boards 20 and 30 are coupled under the condition in which they are positioned on the same plane. Accordingly, the thickness of the light emitting unit 10 can be minimized.

### FIFTH EMBODIMENTS

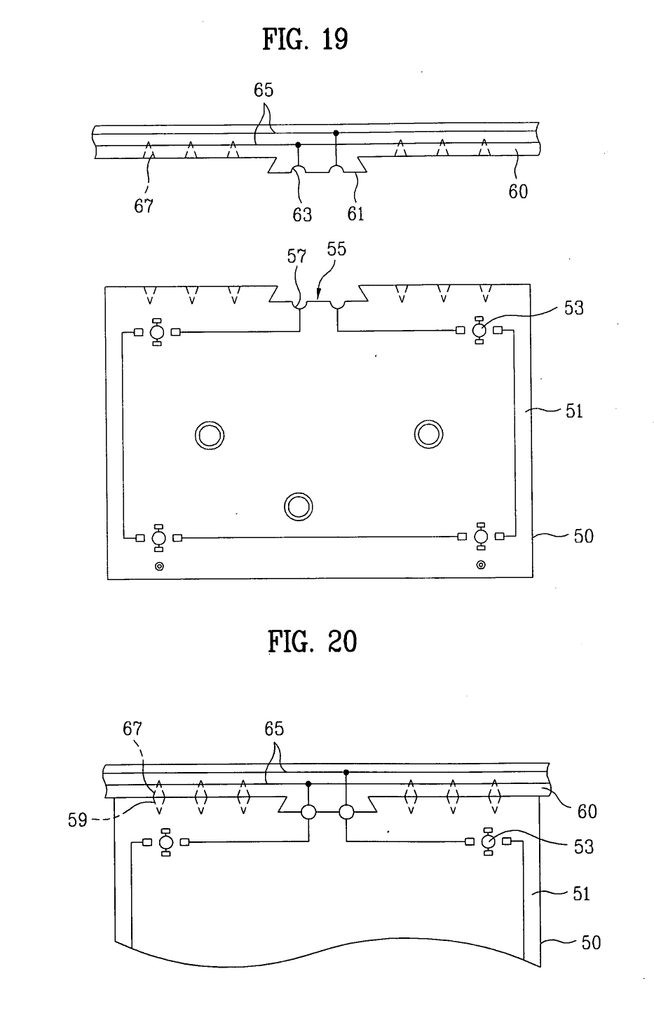

Referring to FIG. 19, a first board 50 is illustrated. The first board 50 has a rectangular shape. The first board 50 includes light emitting devices 53 arranged at respective corners of the first board 50, and connected by a circuit pattern 51. In this embodiment, each light emitting device 53 is illustrated as comprising a light emitting diode emitting monochrome light. Accordingly, the circuit pattern 51, which connects the light emitting devices 53, has a single line structure.

The first board 50 is provided with a recess 55 formed at an edge of the first board 50 facing a second board 55. First grooves 57 having a semicircular shape are formed at the recess 55. The circuit pattern 51 is electrically connected with the first grooves 57. For example, copper is coated over a peripheral surface of each first groove 57. In this case, the circuit pattern 51 is connected to the copper coating. Since the first grooves 57 are connected to the circuit pattern 51, as described above, a signal for turning on/off the light emitting device 53 can be sent to the first board 50 via the first grooves 57.

Although the first grooves 57 are illustrated in the drawing as having a semicircular shape with respect to a planar shape, it is not limited thereto. The first grooves 57 may have various shapes such as triangular and oval shapes.

Coupling patterns 59 are formed on the back surface of the first board 50 at the edge where the recess 55 is formed. The coupling patterns 59 are formed by coating a metallic material such as silver or copper on the back surface of the first board 50. Each coupling pattern 59 has a planar shape having a width increasing gradually as it extends toward the edge. Preferably, each coupling pattern 59 has a triangular shape. Of course, each coupling pattern 59 is not limited to such a shape.

Preferably, the coupling patterns 59 are arranged in pair at opposite sides of the recess 55. The number of coupling patterns 59 is appropriately determined in accordance with the size of the first board 50. In the illustrated case, two coupling pattern groups each including three coupling patterns 59 are arranged at opposite sides of the recess 55, respectively.

Referring to FIG. 19, a second board 60 is also illustrated. The second board 60 has a horizontally-elongated bar shape, in order to enable a plurality of first boards 50 to be coupled to the second board 60. The second board 60 includes a plurality of protrusions 61, which will be coupled with the recesses 55 of the first boards 50, respectively. Each protrusion 61 extends from the second board 60 in one direction. Preferably, each protrusion 61 form male and female coupling shapes, together with the recesses 55 of the first boards 50.

Second grooves 63, which have a shape conforming to that of the first grooves 57, are formed at each protrusion 61. For example, where the first grooves 57 of each first board 50 have a semicircular shape, the second grooves 63 of the second board 60 preferably have a semicircular shape.

Meanwhile, circuit patterns 65 are printed on the second board 60. The circuit patterns 65 extend to the second grooves 63 of the corresponding protrusions 61. Similarly to the first grooves 57, copper is coated over a peripheral surface of each second grooves 63. Accordingly, each second groove 63 is electrically connected to the corresponding circuit pattern 65.

Coupling patterns 67 are formed on the back surface of the second board 60 at the edge where the protrusions 61 are formed. The coupling patterns 67 are formed in the same manner as that of the coupling patterns 58 formed at the first board 50.

Accordingly, when the recess 55 of the first board 50 is fitted around the protrusion 61 of the second board 60, the coupling patterns 59 of the first board 50 and the coupling patterns 67 of the second board 60 are joined, so that they form a diamond shape. In this case, the first grooves 57 and second grooves 63 are also joined, so that they form a circular shape (FIG. 20).

Under this condition, the coupling patterns 59 and 67 are soldered, to couple the first and second boards 50 and 60. The first grooves 57 and second grooves 63 are also soldered, to electrically connect the first and second boards 50 and 60. Preferably, this soldering process is carried out, using a wave soldering process.

Since the first and second boards 50 and 60 are coupled using the coupling patterns 59 and 67, in accordance with the present invention, as described above, it is possible to enhance the coupling force between the first and second boards 50 and 60.

### SIXTH EMBODIMENT

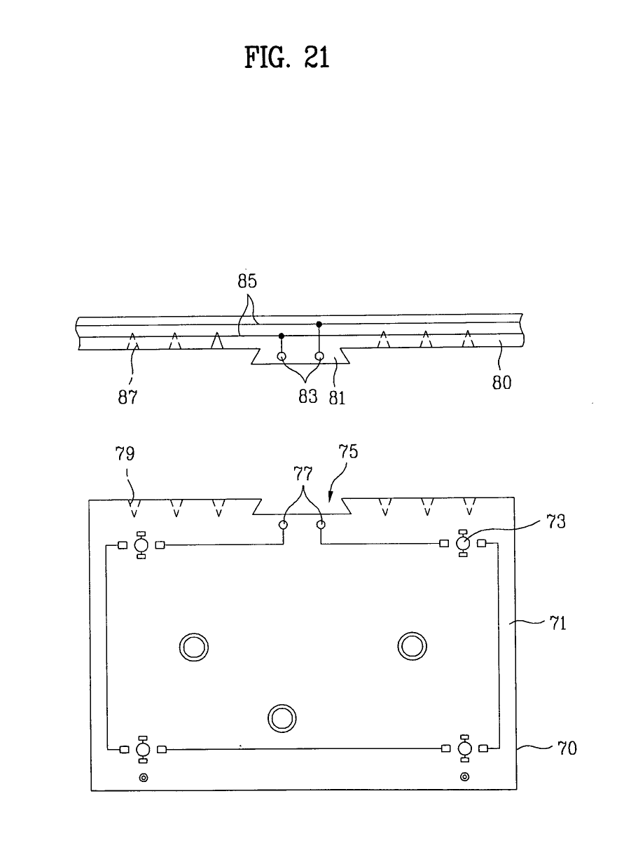

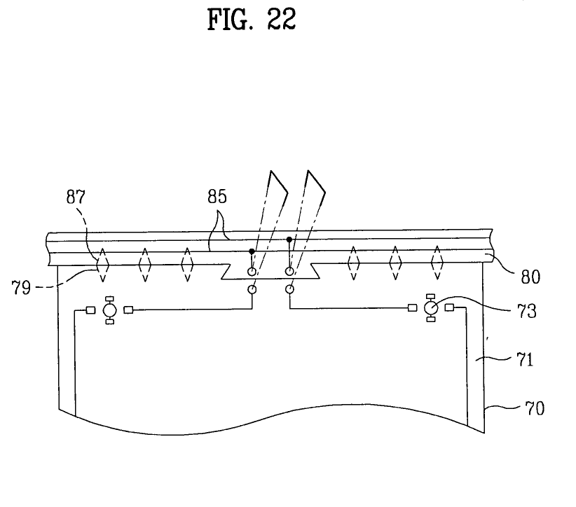

Referring to FIGS. 21 and 22, a first board 70 and a second board 80 are illustrated. First holes 77 and second holes 83 are formed through the first and second boards 70 and 80 at a position adjacent to a groove 75 of the first board 70 and a position adjacent to each protrusion 81 of the second board 80, respectively. A circuit pattern 71 is printed on the first board 70 such that it extends from one first hole 77 to the other first hole 77 via light emitting devices 73, to connect the light emitting devices 73. Circuit patterns 85 are formed on the second board 80 such that they extend to the corresponding second holes 83.

Similarly to the previous embodiments, a metallic material such as copper or silver is coated over the peripheral surfaces of the holes 77 and 83, to electrically connect the holes 77 and 83 to the circuit patterns 71 and 85, respectively.

A conductive jumper 91 is coupled to each of the holes 77 and 83. Accordingly, the first and second boards 70 and 80 are electrically connected via the jumper 91.

Coupling patterns 79 and 87 are formed on the back surfaces of the first and second boards 70 and 80. Accordingly, as the coupling patterns 79 and 87 are soldered, the first and second boards 70 and 80 are coupled.

### SEVENTH EMBODIMENT

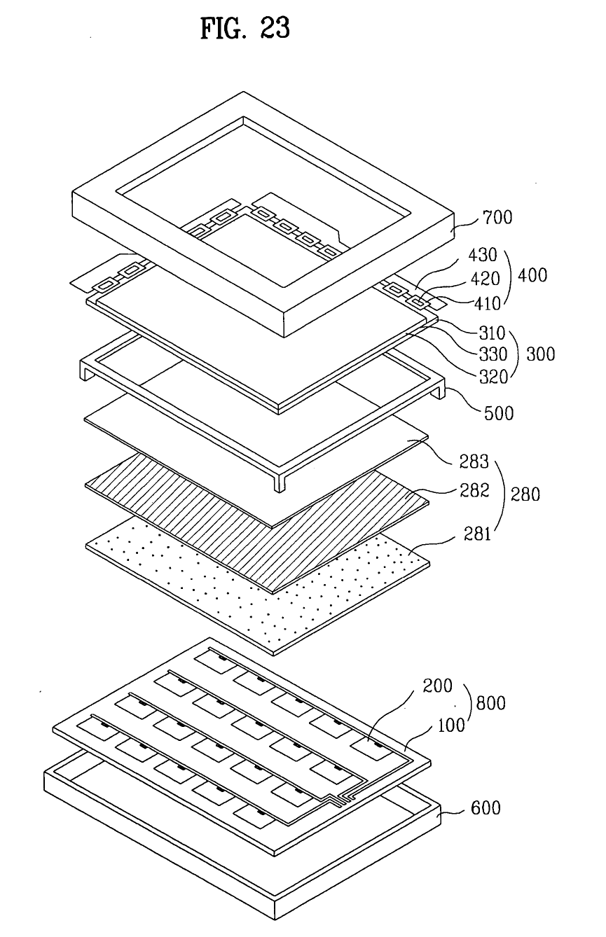

As shown in FIG. 23, a liquid crystal panel 300 may be provided on a backlight unit 800, which includes the above-described light emitting unit 100 including unit modules 200, to constitute a liquid crystal display device.

The liquid crystal panel 300 arranged on the backlight unit 800 includes upper and lower substrates 310 and 320 facing each other, and a liquid crystal layer 330 sealed between the upper and lower substrates 310 and 320.

A driver 400 may be arranged at one side of the liquid crystal panel 300, to drive the liquid crystal panel 300. The liquid crystal display device may further include a molded frame 500 for supporting the sides of the liquid crystal panel 300.

The liquid crystal display device also includes a lower cover 600 for covering the backlight unit 8700, and an upper cover 700 arranged over the liquid crystal panel 300, to cover the upper surface of the liquid crystal panel 300.

The liquid crystal panel 300 includes liquid crystal cells arranged in the form of a matrix. Each liquid crystal cell constitutes a unit pixel. The liquid crystal panel 300 displays an image by adjusting the light transmittance of the liquid crystal cells in accordance with image information sent from the driver 400.

The driver 400 includes a flexible printed circuit (FPC) board 410, drive chips 420 mounted on the FPC board 410, and printed circuit boards (PCBs) 430 connected to respective sides of the FPC board 410. The illustrate driver 400 has a chip-on-film structure. However, the driver 400 may have other known structures, for example, a tape carrier package (TCP) structure and a chip-on-glass (COG) structure. The driver 400 may also be configured such that it is partially mounted on the lower substrate 310.

The molded frame 500 extends along the sides of the liquid crystal panel 300. The molded frame 500 supports the liquid crystal panel 100 such that the liquid crystal panel 100 is maintained to be spaced apart from the backlight unit 800.

The backlight unit 800 is arranged beneath the liquid crystal panel 300, namely, in the rear of the liquid crystal panel 300 in the use state. A plurality of optical sheets 280 may be arranged on the backlight unit 800.

The optical sheets 280 may include a diffusion sheet 281, a prism sheet 282, and a protection sheet 283, which are arranged in the rear of the liquid crystal panel 300. The diffusion sheet 281 diffuses light emitted from the backlight unit 800, and supplies the diffused light to the liquid crystal panel 300.

The prism sheet 282 includes micro-prisms formed on an upper surface of the prism sheet 282 such that the micro-prisms have a certain arrangement. Each micro-prism has a triangular column shape. The prism sheet 282 functions to condense the light diffused by the diffusion sheet 281, in a direction perpendicular to the plane of the liquid crystal panel 300 arranged over the prism sheet 282.

The micro-prisms formed on the prism sheet 282 form a certain angle between adjacent ones thereof. Most light beams passing through the prism sheet 282 travel vertically, thereby providing a uniform brightness distribution.

The protection sheet 283 arranged at the uppermost position protects the prism sheet 282, which is weak against scratch.

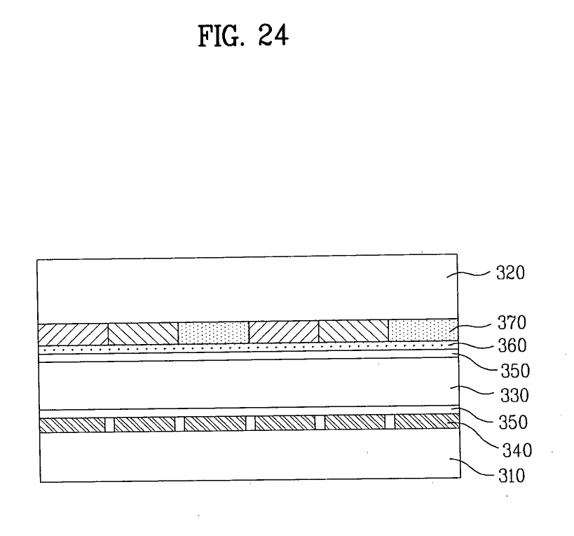

As shown in FIG. 24, a plurality of gate lines and a plurality of data lines are formed on the lower substrate 310 of the liquid crystal panel 300 in the form of a matrix. A pixel electrode and a thin film transistor (TFT) 340 are formed at each intersection of the gate lines and data lines.

A signal voltage applied via the TFT 340 is supplied to the liquid crystal layer 330 by the pixel electrode. In accordance with the signal voltage, the liquid crystal layer 330 is aligned. As a result, the light transmittance of the liquid crystal layer 330 is determined.

Color filters 370 are formed on the upper substrate 320. The color filters 370 constitute R, G, and B pixels rendering desired colors when light passes through the pixels. A common electrode 360, which is made of a transparent conductive material such as indium tin oxide (ITO) or indium zinc oxide (IZO), is also formed on the color filters 370. Alignment films 350 may be arranged on upper and lower surfaces of the liquid crystal layer 330, respectively.

The above-described liquid crystal display device can have an optimal performance as it uses the backlight unit 800 having the above-described configuration.

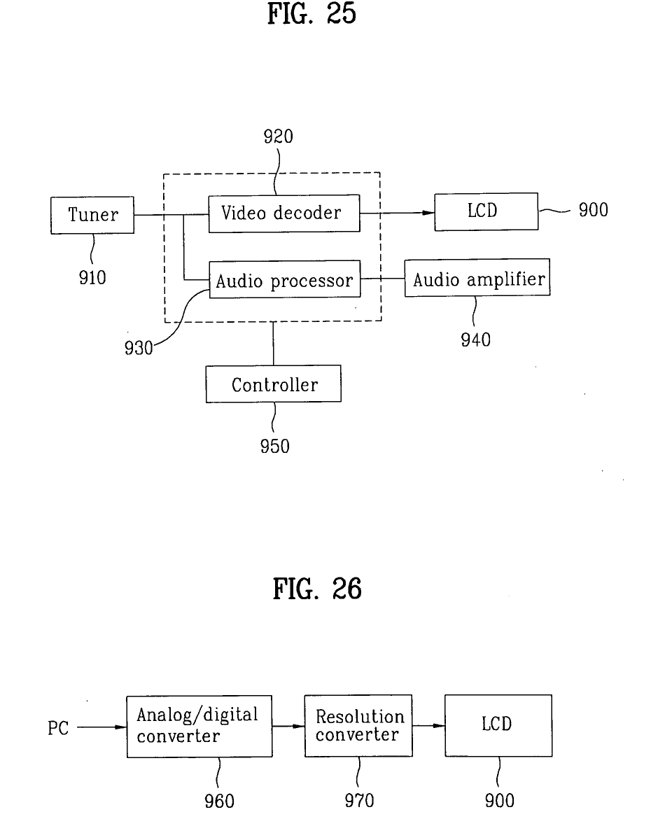

Using the above-described liquid crystal display device, it is possible to constitute a liquid crystal TV as shown in FIG. 25 or a liquid crystal monitor as shown in FIG. 26.

The liquid crystal TV shown in FIG. 25 outputs an image to a liquid crystal display device 900 via a tuner 910 for receiving a broadcast signal and a video decoder 920 for processing the received video signal. An audio processor 930 for processing an audio signal and an audio amplifier 940 for amplifying the processed audio signal are connected to the tuner 910. The video decoder 920 and audio processor 930 may include a controller 950 for controlling the video decoder 920 and audio processor 930, respectively.

Meanwhile, the liquid crystal monitor shown in FIG. 26 includes an analog/digital converter 960 for receiving a video signal from a personal computer (PC), and converting the received video signal to a digital signal, and a resolution converter 970 for converting an output from the analog/digital converter 960 such that the output meets a desired resolution.

When a video signal from the PC is input to the liquid crystal monitor, the analog/digital converter 960 converts the video signal to a digital signal, which is, in turn, displayed on the liquid crystal display device 900. The resolution converter 970 may include a scaler and a deinterlacer.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A light emitting unit comprising:
a circuit board comprising circuit lines and a plurality of connecting members; and
a plurality of unit modules connected to the connecting members of the circuit board, the unit modules including at least one light emitting device.

2. The light emitting unit according to claim 1, wherein each unit module comprises:
a modular circuit board;
the light emitting device coupled to the modular circuit board; and
a circuit formed on the modular circuit board, and electrically connected with the light emitting device.

3. The light emitting unit according to claim 2, wherein the circuit comprises a contact electrically connected to the light emitting device.

4. The light emitting unit according to claim 3, wherein the plurality of connecting members of the circuit board comprises a plurality of contacts coupled with the contacts in the unit modules, respectively.

5. The light emitting unit according to claim 2, wherein a heat discharge member is formed at the modular circuit board.

6. The light emitting unit according to claim 2, wherein the circuit comprises a conductive line connecting the at least one light emitting device.

7. The light emitting unit according to claim 2, wherein a connector is connected to the circuit.

8. The light emitting unit according to claim 7, wherein the plurality of connecting members of the circuit board comprise a plurality of couplers coupled with the connector.

9. The light emitting unit according to claim 1, wherein the unit modules and the circuit board are arranged on a plane flush with a main plane of the light emitting unit.

10. The light emitting unit according to claim 1, further comprising:
a driver connected to the circuit board, to drive the light emitting device coupled to unit module.

11. The light emitting unit according to claim 1, wherein the circuit lines converge to one side of the circuit board.

12. A light emitting unit comprising:
a plurality of first circuit boards, at least one first circuit board including at least one light emitting device electrically connected to a first circuit pattern having a first terminal pattern at the at least one first circuit board; and
a second circuit board including a second circuit pattern having a plurality of second terminal patterns connected to the respective first terminal patterns of the first circuit boards.

13. The light emitting unit according to claim 12, wherein the first and second terminal patterns have a width larger than the first and second circuit pattern.

14. The light emitting unit according to claim 12, wherein the first and second circuit boards further comprise a dummy pattern not connected to the first and second circuit pattern.

15. The light emitting unit according to claim 12, wherein the first circuit board further comprises a plurality of first coupling portions where the first terminal pattern is formed, and the second circuit board further comprises a second coupling portion where the second terminal pattern of the unit module is formed.

16. The light emitting unit according to claim 15, wherein the first coupling portion has a recess shape, and the second coupling portion has a protrusion shape engagable with the recess shape.

17. The light emitting unit according to claim 15, wherein first coupling portion is formed with a first groove electrically connected with a portion of the first circuit pattern, and the second coupling portion of second circuit board is formed with a second groove electrically connected with a portion of the second circuit pattern of the second circuit board while being in contact with the first groove of the first coupling portion corresponding to the second coupling portion, to define a space.

18. The light emitting unit according to claim 15, wherein the first coupling portion is formed with a first hole electrically connected with a portion of the first circuit pattern, and the second coupling portion of the second circuit board is formed with a second hole electrically connected with a portion of the second circuit pattern of the second circuit board.

19. The light emitting unit according to claim 18, wherein at least a pair of the first and second holes is connected by a conductive jumper.

20. A liquid crystal display device comprising:
a backlight unit comprising a circuit board including circuit lines having a plurality of connecting members, and a plurality of unit module connected to the connecting members of the circuit board, the unit modules including at least one light emitting device; and
a liquid crystal panel arranged on the backlight unit.
